(19) United States
(12) Patent Application Publication
(10) Pub. No.: US 2022/0020907 A1
(43) Pub. Date: Jan. 20, 2022

(54) DISPLAY DEVICE, DISPLAY SCREEN AND METHOD FOR MANUFACTURING DISPLAY DEVICE

(71) Applicant: SHENZHEN ROYOLE TECHNOLOGIES CO., LTD., Shenzhen (CN)

(72) Inventors: Ze Yuan, Shenzhen (CN); Haojun Luo, Shenzhen (CN); Jiahao Kang, Shenzhen (CN)

(21) Appl. No.: 17/377,196

(22) Filed: Jul. 15, 2021

(30) Foreign Application Priority Data
Jul. 17, 2020 (CN) 202010696666.0

(51) Int. Cl. H01L 33/62; H01L 25/075; H01L 27/12; H01L 29/786; H01L 33/60

(52) U.S. Cl. CPC H01L 33/62; H01L 25/0753; H01L 2933/0066; H01L 29/78633; H01L 33/60; H01L 27/1214

(57) ABSTRACT

Provided are a display screen, a display device and a manufacturing method thereof. The display device includes: substrate layer, first planarization layer, and thin film transistor layer stacked; and light emitting element provided on the first planarization layer; and an electrical connector is provided on a side of the light emitting element facing the thin film transistor layer, and the electrical connector is exposed from the first planarization layer and electrically connected to the thin film transistor layer. The first planarization layer is provided between the substrate layer and the thin film transistor layer, the light emitting element is provided on the first planarization layer, and the electrical connector of the light emitting element is exposed from the first planarization layer, so that the electrical connection between the thin film transistor layer and the light emitting element can be achieved by metal deposition and patterning on the electrical connector.

### CROSS-REFERENCE TO RELATED APPLICATIONS

This application claims priority to Chinese Patent Application No. 202010696666.0, filed with the Chinese Patent Office on Jul. 17, 2020, entitled “Display Device, Display Screen and Method for Manufacturing Display Device”, which is incorporated herein by reference in its entirety.

### TECHNICAL FIELD

The field belongs to the field of semiconductor technology, and particularly relates to a display device, a display screen, and a method for manufacturing a display device.

### BACKGROUND ART

Light emitting diode (LED) is a commonly used light emitting device that emits energy through the recombination of electrons and holes to emit light. It is widely used in the field of lighting. Light emitting diodes can efficiently convert electrical energy into light energy, and have a wide range of uses in modern society, such as lighting, flat panel displays, and medical devices.

The current LEDs are generally arranged on the side of the thin film transistor layer facing away from the substrate layer and are driven by the thin film transistor layer. Therefore, the LED needs to be bonded with the thin film transistor layer. In this case, there are some limitations in manufacture procedure. For example, solder bumps or eutectic metal are required on electrical connectors such as pads on LEDs, and very thick metal needs to be deposited, and a thermal manufacture procedure is also required. The complicated manufacture procedure is difficult to ensure the flatness of the light emitting element, and there are requirements for the size of the electrical connector, which ultimately limits the size of the LED.

### SUMMARY

The purpose of the present disclosure is to provide a display device, a display screen, and a method for manufacturing the display device, which can simplify the manufacture procedure, so that the flatness of the display device is relatively high, there is no excessive requirement on the size of the pad, and there are no excessive limits to the size of the electrical connector.

In order to achieve the purpose of the present disclosure, the present disclosure provides the following technical solutions.

In a first aspect, the present disclosure provides a display device, including: a substrate layer, a first planarization layer, and a thin film transistor layer that are stacked; and a light emitting element provided on the first planarization layer; and an electrical connector is provided on a side of the light emitting element facing the thin film transistor layer, and the electrical connector is exposed from the first planarization layer and is electrically connected to the thin film transistor layer.

The first planarization layer is provided between the substrate layer and the thin film transistor layer, the light emitting element is provided on the first planarization layer, and the electrical connector of the light emitting element is exposed from the first planarization layer, so that the electrical connection between the thin film transistor layer and the light emitting element can be achieved by metal deposition and patterning on the electrical connector. Therefore, there is no need to provide solder bumps or eutectic metal on the electrical connector, which simplifies the manufacture procedure, the light emitting element is relatively flat, and the electrical connector is not subjected to excessive restrictions, thereby helping reduce the design requirements for light emitting elements.

In an embodiment, the light emitting element is a micro light emitting diode, The micro light emitting diode has higher brightness, higher light emitting efficiency and lower power consumption, thereby improving the light emitting performance of the display device.

In an embodiment, the electrical connector is a pad of the light emitting element, It can be understood that the electrical connector is the pad of the light emitting element, so as to further simplify the manufacture procedure.

In an embodiment, it further includes a package layer covering the thin film transistor layer, and the thin film transistor layer is located between the package layer and the first planarization layer. By disposing the package layer on the side of the thin film transistor layer facing away from the first planarization layer, it is beneficial to ensure the flatness of the light emitting element.

In an embodiment, the thin film transistor layer comprises a metal layer, and the metal layer passes through the thin film transistor layer and is electrically connected to the electrical connector. The metal layer is provided, and the metal layer passes through the thin film transistor layer and is electrically connected to the electrical connector, so that there is no need to provide solder bumps or eutectic metal on the electrical connector, which simplifies the manufacture procedure and helps to improve the flatness and reduce the design requirements on the light emitting element.

In an embodiment, the thin film transistor layer further comprises a second planarization layer, the light emitting element comprises an electrode sheet connected to the electrical connector, wherein the second planarization layer covers the electrode sheet, and the metal layer passes through the second flattening layer and is electrically connected to the electrode sheet. By arranging the metal layer to pass through the second planarization layer to be electrically connected to the electrode sheet, the manufacture procedure is relatively simple. Moreover, the second planarization layer covers the electrode sheet to prevent adjacent electrode sheets from contacting to occur short circuit, which can improve the yield of the display device. In addition, by covering the electrode sheet with the second planarization layer, the flatness of the display device can be further improved.

In an embodiment, a plurality of light emitting elements are provided, and the plurality of light emitting elements are arranged at intervals; the thin film transistor layer comprises a plurality of thin film transistors in one-to-one correspondence with the light emitting elements; and two adjacent light emitting elements are connected by a flexible connector. By arranging the flexible connector, the flexible connector connects the adjacent light emitting elements, which is beneficial for the display device to realize a stretchable design and a bendable design.

In an embodiment, the flexible connector comprises at least one of a patterned substrate layer, a patterned thin film transistor layer and a patterned first planarization layer, wherein the patterned substrate layer is of a flexible polymer film. By providing a patterned substrate layer made of a flexible polymer film, the flexible connector can connect adjacent light emitting elements and can be deformed to a certain extent, thereby realizing a stretchable design. By providing a patterned thin film transistor layer, the flexible connector can connect adjacent light emitting elements, and can be deformed to a certain degree, thereby achieving a stretchable design. Similarly, the patterned first planarization layer can also support a certain degree of stretching deformation, thereby realizing a stretchable design. In addition, the patterned first planarization layer also functions as a support and can fix the light emitting element between the substrate layer and the thin film transistor layer corresponding to each other.

In an embodiment, the patterned thin film transistor layer is partially etched. The patterned thin film transistor layer is formed by partial etching, the process is simple, and it is convenient to design a pattern with good ductility.

In an embodiment, the patterned thin film transistor layer comprises a second planarization layer, a barrier layer, a light-shielding plate insulating layer, a gate insulating layer, an interlayer dielectric layer and a passivation layer that are stacked. It is understandable that the barrier layer has better sealing properties, which can reduce the penetration of water, oxygen, and light into the thin film transistor layer, thereby inhibiting the generation of defect state.

In an embodiment, at least one of the interlayer dielectric layer, the gate insulating layer, the light-shielding plate insulating layer and the barrier layer in the patterned thin film transistor layer is etched. By etching at least one of the interlayer dielectric layer, the gate insulating layer, the light-shielding plate insulating layer, and the barrier layer, the thin film transistor layer is patterned, thereby completing the stretchable design.

In an embodiment, the thin film transistor layer further comprises a light-shielding layer, an active layer, a gate layer and a source-drain layer, wherein the light-shielding plate insulating layer is configured to make the active layer insulated from the light-shielding layer; the gate insulating layer is configured to make the gate layer insulated from the active layer; the interlayer dielectric layer is configured to make the source-drain layer insulated from the gate layer; and the passivation layer is configured to overall protect the thin film transistor layer. It is understandable that the light-shielding plate insulating layer insulates the active layer and the light-shielding layer, and thus avoids short-circuiting of the metal layer connected to the light-shielding layer and the active layer. The gate insulating layer insulates the gate layer and the active layer to avoid short-circuiting of the gate layer and the active layer. The interlayer dielectric layer insulates the source-drain layer and the gate layer to avoid short-circuiting of the source-drain layer and the gate layer. Through the above arrangement, the yield of the display device can be effectively improved, and meanwhile, the passivation layer overall protects the thin film transistor layer, so that the thin film transistor layer has good structural strength.

In an embodiment, the flexible connector is curved, The curved flexible connector has good ductility and can support a greater degree of stretching deformation of the display device.

In an embodiment, a light emitting surface of the light emitting element faces the thin film transistor layer and/or the substrate layer. By arranging the light emitting surface to face the thin film transistor layer and/or the substrate layer, the light emitting element has a variety of light-emitting solutions, which is beneficial for the display device to be suitable for various display screens, and improves the applicability of the display device.

In an embodiment, the thin film transistor layer and/or the substrate layer on the side of the light emitting element facing the light emitting surface has a corresponding light-transmitting area. By providing the light-transmitting area, the light of the light emitting element can be emitted through the light-transmitting area.

In an embodiment, the light-transmitting area of the thin film transistor layer corresponding to the light emitting element is made of a light-transmitting material, and/or the substrate layer is made of a light-transmitting material. By providing the light-transmitting area of the thin film transistor layer made of a light-transmitting material, the light passing rate of the light emitting element in the light-transmitting area of the thin film transistor layer is relatively high, which is beneficial to improve the light-emitting brightness of the side of the light emitting element at the thin film transistor layer; and the substrate layer is made of light-transmitting material, which makes the light passing rate of the light emitting element higher in the substrate layer, which is beneficial to improve the light-emitting brightness of the side of the light emitting element at the substrate layer.

In an embodiment, a reflective layer is provided on the shady face of the light emitting element. By arranging the reflective layer on the shady face of the light emitting element, the reflective layer reflects light from all directions of the light emitting element to the light emitting surface, thereby improving the light emitting efficiency, which is beneficial to improve the brightness of the display device and reduce the power consumption of the display device.

In an embodiment, the reflective layer is electrically connected to the light emitting element, and the reflective layer and the electrode sheet jointly drive the light emitting element. It can be understood that the electrode sheet is the upper electrode of the vertical light emitting element, the reflective layer is the lower electrode of the light emitting element, and the upper and lower electrodes simultaneously drive the light emitting element. Specifically, a channel can be formed by etching or drilling, so as to electrically connect the reflective layer to the thin film transistor layer. By arranging the reflective layer to be electrically connected to the light emitting element, the reflective layer can integrate the functions of reflecting and driving without additionally providing lower electrode, thereby simplifying the manufacture procedure of the display device.

In an embodiment, the light emitting surface of the light emitting element faces the thin film transistor layer, and a light blocking layer is provided on the thin film transistor layer, wherein light is transmitted at an area of the light blocking layer corresponding to the light emitting element, and the other areas do not transmit light. It can be understood that the light blocking layer can prevent the light emitted by the light emitting element from being scattered.

In an embodiment, the light emitting element comprises a blue-light micro light emitting diode, a red light conversion layer and a green light conversion layer, wherein the red light conversion layer is disposed on a light emitting surface of the blue-light micro light emitting diode and emits red light; the green light conversion layer is disposed on the light emitting surface of the blue-light micro light emitting diode and emits green light; and filter layers are provided on the red light conversion layer and the green light conversion layer. By arranging blue-light micro light emitting diode, red light conversion layer and green light conversion layer, the light emitting element can emit light of three colors of red, green and blue only by using blue-light micro light emitting diode, and only needs to migrate blue-light micro light emitting diode once in the migration process. Compared with the red-light micro light emitting diode and the green-light micro light emitting diode, the blue-light micro light in emitting diode has higher efficiency performance, which is beneficial to the high-efficiency display of the display device. It is understandable that if the solution including blue-light micro light emitting diode, green-light micro light emitting diode and red-light micro light emitting diode is adopted, migration processes are required to be performed three times, and thus the manufacture procedure is relatively complicated. The blue-light micro light emitting diode cooperates with the red light conversion layer and the green light conversion layer to emit red light and green light, so that the light quantum yield only needs to reach 70%. This embodiment is better than the solution including blue-light micro light emitting diode, green-light micro light emitting diode and red-light micro light emitting diode, and the efficiency of the display device is higher.

In a second aspect, the present disclosure also provides a display screen, which includes the display device described in any one of the embodiments of the first aspect. By adding the display device provided by the present disclosure to the display screen, the manufacture procedure of the display screen is relatively simple, and the flatness is higher.

In a third aspect, the present disclosure also provides a method for manufacturing a display device, The manufacturing method includes; manufacturing a light emitting element on a substrate layer; forming a first planarization layer on the substrate layer so that the first planarization layer covers the light emitting element; and forming a thin film transistor layer on a side of the first planarization layer facing away from the substrate layer, so that the thin film transistor layer is electrically connected to the light emitting element. By manufacturing the light emitting element on the substrate layer and forming the first planarization layer on the substrate layer, the first planarization layer covers the light emitting element, the light emitting element manufactured by this method has a higher degree of flatness.

In an embodiment, the manufacturing a light emitting element on a substrate layer includes: inverting the light emitting element to the substrate layer, so as to make an electrical connector of the light emitting element face the thin film transistor layer. By inverting the light emitting element to the substrate layer, the electrical connector of the light emitting element faces the thin film transistor layer, so that the electrical connector is electrically connected to the thin film transistor layer.

In an embodiment, the forming a thin film transistor layer on a side of the first planarization layer facing away from the substrate layer, so that the thin film transistor layer is electrically connected to the light emitting element, includes: etching at a position of the first planarization layer corresponding to the light emitting element, so that the electrical connector of the light emitting element is exposed from the first planarization layer. The electrical connector is exposed from the first planarization layer by etching, so that the electrical connector is electrically connected to the thin film transistor layer, and the manufacture procedure is relatively simple, which is beneficial to improve the yield of the display device.

In an embodiment, an electrode sheet is deposited on the electrical connector, and the electrode sheet is electrically connected to the thin film transistor layer. By depositing electrode sheet on the electrical connector, there is no need to provide solder bumps and eutectic metal, and no thermal manufacture procedure is required, which is beneficial to simplify the manufacture procedure of the display device.

In an embodiment, the method further includes: forming a second planarization layer and a metal layer sequentially on the side of the first planarization layer facing away from the substrate layer, so that the second planarization layer covers the electrode sheet, and the metal layer passes through the second planarization layer and is electrically connected to the electrode sheet. The second planarization layer and the metal layer are provided, the metal layer passes through the second planarization layer to be electrically connected to the electrode sheet, the process is relatively simple, and the second planarization layer covers the electrode sheet, which can avoid the short-circuiting of adjacent electrode sheets, thereby improving the yield of the display device. Moreover, the second planarization layer is provided to cover the electrode sheet, which can further improve the flatness of the display device.

### BRIEF DESCRIPTION OF DRAWINGS

In order to more clearly illustrate technical solutions in embodiments of the present disclosure or the prior art, accompanying drawings which need to be used for description of the embodiments or the prior art will be introduced briefly below. Apparently, the accompanying drawings in the description below merely show some embodiments of the present disclosure, and those ordinarily skilled in the art still could obtain other accompanying drawings in light of these accompanying drawings, without inventive efforts.

FIG. 1 is a schematic structural diagram of a display device in a first embodiment of the present disclosure;

FIG. 2 is a schematic structural diagram of a display device in a second and a third embodiments of the present disclosure;

FIG. 3 is a schematic structural diagram of a display device in a fourth embodiment of the present disclosure;

FIG. 4 is a schematic structural diagram of a display device in a fifth and a sixth embodiments of the present disclosure;

FIG. 5 is a schematic structural diagram of a display device in a seventh embodiment of the present disclosure;

FIG. 6 is a schematic structural diagram of a display device in an eighth embodiment of the present disclosure;

FIG. 7 is a schematic structural diagram of a display device in a ninth embodiment of the present disclosure;

FIG. 8 is a schematic structural diagram of a display device in an eighth and a tenth embodiments of the present disclosure;

FIG. 9 is a schematic structural diagram of a display device with a plurality of light emitting elements in the first embodiment of the present disclosure;

FIG. 10 is a schematic structural diagram of a display device with a plurality of light emitting elements in the second embodiment of the present disclosure;

FIG. 11 is a schematic structural diagram of a display device with a plurality of light emitting elements in the third embodiment of the present disclosure;

FIG. 12 is a schematic structural diagram of a display device with a plurality of light emitting elements in the fourth embodiment of the present disclosure;

FIG. 13 is a schematic structural diagram of a display device with a plurality of light emitting elements in the fifth embodiment of the present disclosure;

FIG. 14 is a schematic structural diagram of a display device with a plurality of light emitting elements in the sixth and the seventh embodiments of the present disclosure;

FIG. 15 is a schematic structural diagram of a display device with a plurality of light emitting elements in the ninth embodiment of the present disclosure;

FIG. 16 is a schematic structural diagram of a display device with a plurality of light emitting elements in the tenth embodiment of the present disclosure;

FIG. 17 is a schematic structural diagram of a display device with a plurality of light emitting elements in an eleventh embodiment of the present disclosure;

FIG. 18 is a schematic structural diagram of a display device with a plurality of light emitting elements in a twelfth embodiment of the present disclosure;

FIG. 19 is a schematic structural diagram of a flexible connector connecting adjacent light emitting elements in an embodiment of the present disclosure; and

FIG. 20 is a schematic flowchart of a method for manufacturing a display device in an embodiment of the present disclosure.

### DETAILED DESCRIPTION OF EMBODIMENTS

Technical solutions in the embodiments of the present disclosure will be described clearly and completely below in combination with the accompanying drawings in the embodiments of the present disclosure, apparently, the embodiments described are merely some but not all embodiments of the present disclosure. Based on the embodiments of the present disclosure, all other embodiments obtained by those of ordinary skill in the art without inventive effort shall fall within the protection scope of the present disclosure.

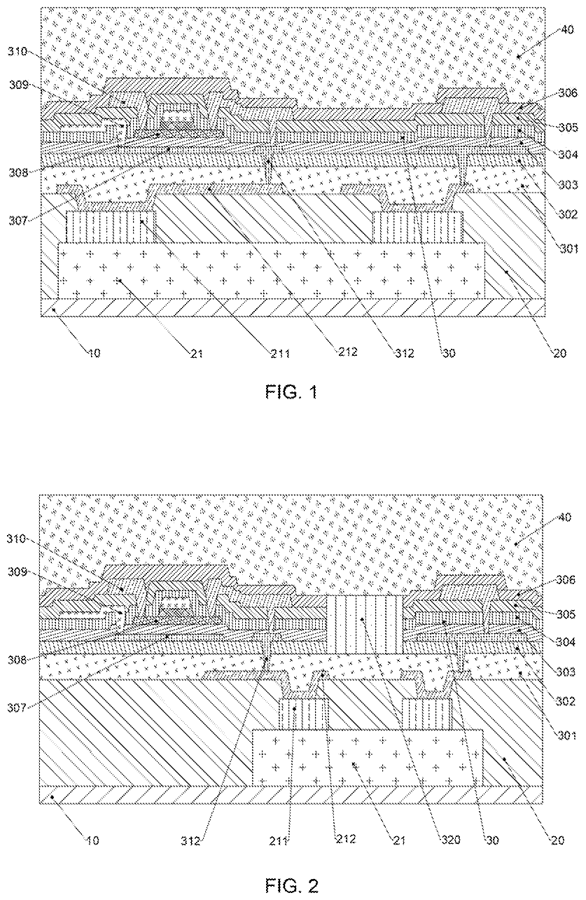

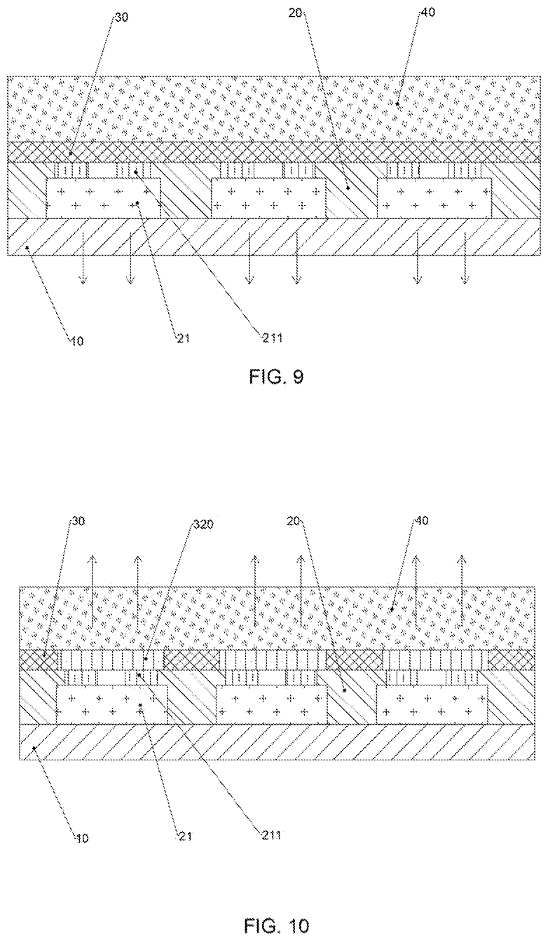

Please refer to FIG. 1 and FIG. 9, a first embodiment of the present disclosure provides a display device, which can be applied to electronic devices such as tablet computers, smart phones, personal digital assistants, and televisions. The display device comprises:

a substrate layer 10, a first planarization layer 20 and a thin film transistor layer 30 that are stacked; and

a light emitting element 21 provided on the first planarization layer 20,

wherein a side of the light emitting element 21 facing the thin film transistor layer 30 is provided with an electrical connector 211, and the electrical connector 211 is exposed from the first planarization layer 20 and is electrically connected to the thin film transistor layer 30.

Specifically, the first planarization layer 20 is generally made of a photosensitive organic material. The first planarization layer 20 can fix the light emitting element 21 on the substrate layer 10 and is equivalent to an indirect substrate of the thin film transistor layer 30. Preferably, the material of the first planarization layer 20 is the same as that of the substrate layer 10. When the material of the substrate layer 10 is polyimide, the material of the first planarization layer 20 is also polyimide. The number of light emitting elements 21 may be one or more. The thin film transistor layer 30 has at least one thin film transistor, and the number of thin film transistors is preferably the same as the number of light emitting elements 21. The electrical connector 211 is preferably a pad of the light emitting element 21, in order to simplify the process of electrically connecting the light emitting element 21 to the thin film transistor layer 30. The light emitting element 21 is a micro light emitting diode. The micro light emitting diode has high brightness, high light emitting efficiency and low power consumption, thereby improving the light emitting performance of the display device.

It is understandable that if the light emitting element 21 is arranged on the side of the thin film transistor layer 30 facing away from the substrate layer 10, the light emitting element 21 and the thin film transistor need to be bonded, and the electrical connector 211 needs to be provided with pad bumps or eutectic metal, which requires the deposition of very thick metal, and requires heating during the bonding process, which makes the manufacture procedure quite complicated. The complexity of the manufacture procedure makes it difficult to guarantee the flatness of the light emitting element 21, and because of the need to deposit thicker metal, the size of the electrical connector 211 needs to meet certain requirements, which ultimately results in the size of the light emitting element 21 being limited, and higher design requirements for the light emitting element 21, thus the cost is higher.

The first planarization layer 20 is provided between the substrate layer 10 and the thin film transistor layer 30, the light emitting element 21 is provided on the first planarization layer 20, and the electrical connector 211 of the light emitting element 21 is exposed from the first planarization layer 20, so that the electrical connection between the thin film transistor layer 30 and the light emitting element 21 can be achieved by metal deposition and patterning on the electrical connector 211. Therefore, there is no need to provide solder bumps or eutectic metal on the electrical connector 211, which simplifies the manufacture procedure, the light emitting element 21 is relatively flat, and the electrical connector 211 is not subjected to excessive restrictions, thereby helping reduce the design requirements on light emitting elements 21.

In an embodiment, referring to FIG. 1, the display device further includes a protective layer 40. The protective layer 40 covers the side of the thin film transistor layer 30 facing away from the first planarization layer 20, and the protective layer 40 is used to protect the thin film transistor layer 30. Specifically, the material of the protective layer 40 is preferably an elastic material, so that the display device can meet the design requirement of stretchability.

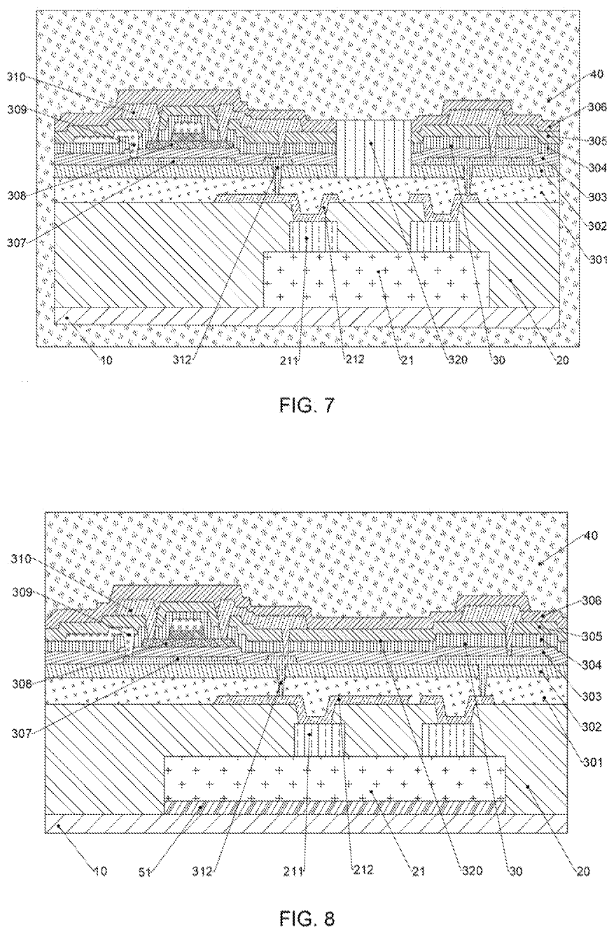

In an embodiment, referring to FIG. 7, the protective layer 40 covers the thin film transistor layer 30, the first planarization layer 20 and the substrate layer 10, and the protective layer 40 is made of elastic material to facilitate the realization of a stretchable design.

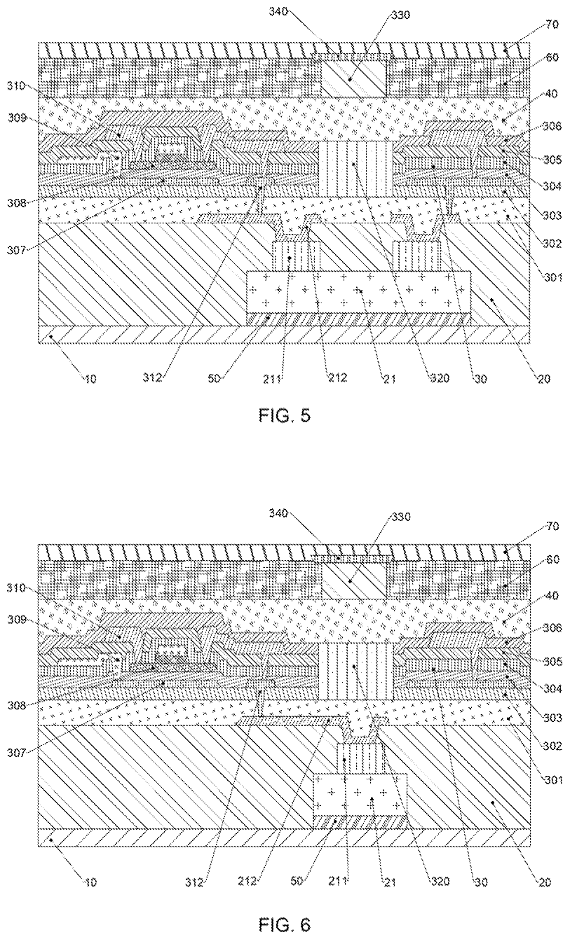

In an embodiment, referring to FIGS. 5 and 6, the display device further includes a package layer 70 covering the thin film transistor layer 30. The thin film transistor layer 30 is located between the package layer 70 and the first planarization layer 20. Specifically, the package layer 70 is provided on the side of the protective layer 40 facing away from the thin film transistor layer 30. By disposing the package layer 70 on the side of the thin film transistor layer 30 facing away from the first planarization layer 20, it is beneficial to ensure the flatness of the light emitting element 21. Moreover, the package layer 70 has a protective effect on the thin film transistor layer 30, the first planarization layer 20, and the substrate layer 10 under the package layer 70. Meanwhile, the sealing performance of the package layer 70 is good.

In an embodiment, referring to FIG. 1, the thin film transistor layer 30 includes a metal layer 312. The metal layer 312 passes through the thin film transistor layer 30 and is electrically connected to the electrical connector 211. The metal layer 312 is provided, and the metal layer 312 passes through the thin film transistor layer 30 and is electrically connected to the electrical connector 211, so that there is no need to provide solder bumps or eutectic metal on the electrical connector 211, which simplifies the manufacture procedure and helps to improve the flatness and reduce the design requirements on the light emitting element 21.

In an embodiment, referring to FIG. 1, the thin film transistor layer 30 further includes a second planarization layer 301. The light emitting element 21 includes an electrode sheet 212 connected to the electrical connector 211, the second planarization layer 301 covers the electrode sheet 212, and the metal layer 312 passes through the second planarization layer 301 and is electrically connected to the electrode sheet 212. Specifically, the material of the second planarization layer 301 is the same as the material of the first planarization layer 20. It can be understood that the electrode sheet 212 of the electrical connector 211 generally has a positive electrode and a negative electrode, and the second planarization layer 301 can effectively isolate the electrode sheet 212 of the positive electrode and the electrode sheet 212 of the negative electrode to avoid short circuit. By arranging the metal layer 312 to pass through the second planarization layer 301 to be electrically connected to the electrode sheet 212, the manufacture procedure is relatively simple. Moreover, the second planarization layer 301 covers the electrode sheet 212 to prevent adjacent electrode sheets 212 from contacting to occur short circuit, which can improve the yield of the display device. In addition, by covering the electrode sheet 212 with the second planarization layer 301, the flatness of the display device can be further improved. It can be understood that, compared with arranging the electrode sheet 212 on a plane, the process of covering the electrode sheet 212 with the second planarization layer 301 with a higher degree of flatness is simpler and more effective.

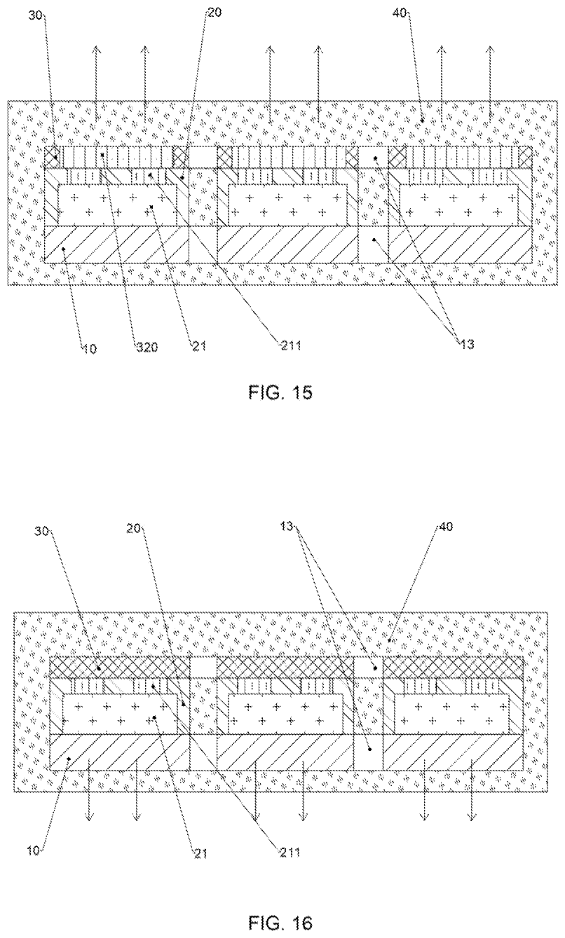

In an embodiment, referring to FIG. 15, the number of light emitting elements 21 is multiple. The plurality of light emitting elements 21 are arranged at intervals. The thin film transistor layer 30 includes a plurality of thin film transistors corresponding to the light emitting elements 21 in a one-to-one manner. Two adjacent light emitting elements 21 are connected by a flexible connector 13. By arranging the flexible connector 13, the flexible connector 13 connects the adjacent light emitting elements 21, which is beneficial for the display device to realize a stretchable design and a bendable design.

In an embodiment, referring to FIGS. 15 to 18, the flexible connector 13 includes a patterned substrate layer 10. The patterned substrate layer 10 is a flexible polymer film. Specifically, the flexible polymer film is preferably a polyimide film. In other embodiments, the substrate layer 10 may also be glass. The patterned substrate layer 10 is provided, the substrate layer 10 is a flexible polymer film, so that the flexible connector 13 can connect the adjacent light emitting elements 21 and can be deformed to a certain extent, thereby achieving a stretchable design.

In an embodiment, referring to FIGS. 15 to 18, the flexible connector 13 includes a patterned thin film transistor layer 30. By providing a patterned thin film transistor layer 30, the flexible connector 13 can connect adjacent light emitting elements 21, and can be deformed to a certain degree, thereby achieving a stretchable design.

In an embodiment, referring to FIGS. 15 to 18, the flexible connector 13 includes a patterned first planarization layer 20. By providing a patterned planarization layer 20, the flexible connector 13 can connect adjacent light emitting elements 21, and can be deformed to a certain degree, thereby achieving a stretchable design. In addition, the patterned first planarization layer 20 also functions as a support and can fix the light emitting element 21 between the substrate layer 10 and the thin film transistor layer 30 corresponding to each other.

Specifically, the flexible connector 13 includes at least one of a patterned thin film transistor layer 30, a patterned substrate layer 10, and a patterned first planarization layer 20 to ensure that the display device can be stretched and deformed.

In an embodiment, referring to FIGS. 15 to 18, the patterned thin film transistor layer 30 is partially etched. The patterned thin film transistor layer 30 is formed by partial etching, the process is simple, and it is convenient to design a pattern with good ductility.

In an embodiment, referring to FIG. 1, the patterned thin film transistor layer 30 includes a second planarization layer 301, a barrier layer 302, a light-shielding plate insulating layer 303, a gate insulating layer 304, an interlayer dielectric layer 305 and a passivation layer 306 that are stacked. It is understandable that the barrier layer 302 has better sealing properties, which can reduce the penetration of water, oxygen, and light into the thin film transistor layer 30, thereby inhibiting the generation of defect state.

In an embodiment, referring to FIG. 1, at least one of the interlayer dielectric layer 305, the gate insulating layer 304, the light-shielding plate insulating layer 303 and the barrier layer 302 in the patterned thin film transistor layer 30 is etched. By etching at least one of the interlayer dielectric layer 305, the gate insulating layer 304, the light-shielding plate insulating layer 303, and the barrier layer 302, the thin film transistor layer 30 is patterned, thereby completing the stretchable design.

In an embodiment, referring to FIG. 1, the thin film transistor layer 30 further includes a light-shielding layer 307, an active layer 308, a gate layer 309, and a source-drain layer 310. The light-shielding plate insulating layer 303 is configured to make the active layer 308 insulated from the light-shielding layer 307. The gate insulating layer 304 is configured to make the gate layer 309 insulated from the active layer 308. The interlayer dielectric layer 305 is configured to make the source-drain layer 310 insulated from the gate layer 309. The passivation layer 306 is configured to overall protect the thin film transistor layer 30. It is understandable that the light-shielding plate insulating layer 303 insulates the active layer 308 and the light-shielding layer 307, and thus avoids short-circuiting of the metal layer 312 connected to the light-shielding layer 307 and the active layer 308. The gate insulating layer 304 insulates the gate layer 309 and the active layer 308 to avoid short-circuiting of the gate layer 309 and the active layer 308. The interlayer dielectric layer 305 insulates the source-drain layer 310 and the gate layer 309 to avoid short-circuiting of the source-drain layer 310 and the gate layer 309. Through the above arrangement, the yield of the display device can be effectively improved, and meanwhile, the passivation layer 306 overall protects the thin film transistor layer 30, so that the thin film transistor layer 30 has good structural strength.

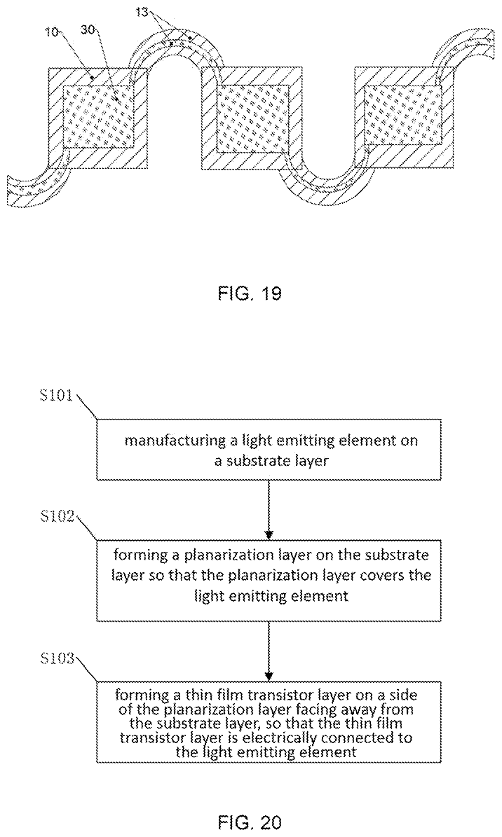

In an embodiment, referring to FIG. 19, the flexible connector 13 is curved. The curved flexible connector 13 has good ductility and can support a greater degree of stretching deformation of the display device.

In an embodiment, referring to FIGS. 9 to 11, a light emitting surface of the light emitting element 21 faces the thin film transistor layer 30 and/or the substrate layer 10. By arranging the light emitting surface to face the thin film transistor layer 30 and/or the substrate layer 10, the light emitting element 21 has a variety of light-emitting solutions, which is beneficial for the display device to be suitable for various display screens, and improves the applicability of the display device. Specifically, the light emitting surfaces of the light emitting element 21 may respectively face the thin film transistor layer 30 and the substrate layer 10, so that the light emitting element 21 emits light toward the thin film transistor layer 30 and the substrate layer 10 at the same time. Alternatively, the light emitting surface of the light emitting element 21 only faces the thin film transistor layer 30 or the substrate layer 10 so that the light emitting element 21 emits light toward the thin film transistor layer 30 or the substrate layer 10.

In an embodiment, referring to FIGS. 9 to 11, the thin film transistor layer 30 and/or the substrate layer 10 on the side of the light emitting element 21 facing the light emitting surface has a corresponding light-transmitting area 320. By providing the light-transmitting area 320, the light of the light emitting element 21 can be emitted through the light-transmitting area 320. Specifically, a light-transmitting area 320 may be provided on the thin film transistor layer 30 and the substrate layer 10 at the same time, so that the light emitting element 21 can emit light from both sides. Alternatively, the light-transmitting area 320 is provided only on the thin film transistor layer 30 or the substrate layer 10, so that the light emitting element 21 emits light from single side.

In an embodiment, referring to FIGS. 9 to 11, the light-transmitting area 320 of the thin film transistor layer 30 corresponding to the light emitting element 21 is made of a light-transmitting material, and/or the substrate layer 10 is made of a light-transmitting material, Specifically, the substrate layer 10 is made of a colorless polyimide material. Preferably, the transmittance of the substrate layer 10 to light is higher than 60%. Of course, the present disclosure does not limit the transmittance of the substrate layer 10. By providing the light-transmitting area 320 of the thin film transistor layer 30 made of a light-transmitting material, the light passing rate of the light emitting element 21 in the light-transmitting area 320 of the thin film transistor layer 30 is relatively high, which is beneficial to improve the light-emitting brightness of the side of the light emitting element 21 at the thin film transistor layer 30; and the substrate layer 10 is made of light-transmitting material, which makes the light passing rate of the light emitting element 21 higher in the substrate layer 10, which is beneficial to improve the light-emitting brightness of the side of the light emitting element 21 at the substrate layer 10.

In an embodiment, referring to FIGS. 5 and 14, a reflective layer 50 is provided on the shady face of the light emitting element 21. By arranging the reflective layer 50 on the shady face of the light emitting element 21, the reflective layer 50 reflects light from all directions of the light emitting element 21 to the light emitting surface, thereby improving the light emitting efficiency, which is beneficial to improve the brightness of the display device and reduce the power consumption of the display device. Specifically, the light emitting element 21 and the substrate layer 10 can be bonded through the reflective layer 50 so that the light emitting element 21 is fixed to the substrate layer 10. Of course, in an embodiment where the reflective layer 50 is not provided, an adhesive liner may also be provided to connect and fix the substrate layer 10 and the light emitting element 21. If it is necessary to emit light from the substrate layer 10, the adhesive liner can be made of a light-transmitting material. When only the side of the light emitting element 21 on the substrate layer 10 emits light, the reflective layer 50 can be an electrode sheet 212, which is made of a metal material that can reflect light, so that it can be electrically connected, at the same time, the light from the light emitting element 21 can be reflected to the light-transmitting area 320 of the substrate layer 10. Alternatively, when only the side of the light emitting element 21 on the thin-film transistor layer 30 emits light, the reflective layer 50 may be provided between the substrate layer 10 and the light emitting element 21, so that the reflective layer 50 can connect the light emitting element 21 and the substrate layer 10, and simultaneously, the light of the light emitting element 21 is reflected to the light-transmitting area 320 of the thin film transistor layer 30.

In an embodiment, referring to FIGS. 6 and 8, the reflective layer 50 is electrically connected to the light emitting element 21, and the reflective layer 50 and the electrode sheet 212 jointly drive the light emitting element 21. It can be understood that the electrode sheet 212 is the upper electrode of the vertical light emitting element 21, the reflective layer 50 is equivalent to the lower electrode 51 of the light emitting element 21, and the upper and lower electrodes simultaneously drive the light emitting element 21. By arranging the reflective layer 50 to be electrically connected to the light emitting element 21, the reflective layer 50 can integrate the functions of reflecting and driving without additionally providing lower electrode 51, thereby simplifying the manufacture procedure of the display device. Specifically, a channel can be formed by etching or drilling or other methods, so as to electrically connect the reflective layer 50 to the metal layer 312 in the thin film transistor layer 30. For example, the reflective layer 50 can be similar to the electrode sheet 212 on the right side of the light emitting element 21 in FIG. 7, and the metal layer 312 is electrically connected to the reflective layer 50 by passing through the second planarization layer 301. Specifically, a part of the reflective layer 50 can be extended into the second planarization layer 301 to be electrically connected to the metal layer 312, or the metal layer 312 is further passed through the first planarization layer 20 to be electrically connected to the reflective layer 50. Preferably, the reflective layer 50 can reflect more than 70% of the light energy incident on the reflective layer 50 back to the original incident side.

In an embodiment, referring to FIG. 4 and FIG. 5, the light emitting element 21 includes a blue-light micro light emitting diode and a light conversion layer 330 (a red light conversion layer and a green light conversion layer). The red light conversion layer is arranged on a side of the light emitting surface of the blue-light micro light emitting diode and emits red light. The green light conversion layer is arranged on a side of the light emitting surface of the blue-light micro light emitting diode and emits green light. A filter layer 340 is provided on the red light conversion layer and the green light conversion layer. The material of the light conversion layer is preferably a quantum dot material with a high light conversion rate. By arranging blue-light micro light emitting diode, red light conversion layer and green light conversion layer, the light emitting element 21 can emit light of three colors of red, green and blue only by using the blue-light micro light emitting diode, and only needs to transfer the blue-light micro light emitting diode once in the transfer process. Compared with the red-light micro light emitting diode and the green-light micro light emitting diode, the blue-light micro light emitting diode has higher efficiency performance, which is beneficial to the high-efficiency display of the display device. It is understandable that if the solution including blue-light micro light emitting diode, green-light micro light emitting diode and red-light micro light emitting diode is adopted, transfer processes are required to be performed three times, and thus the manufacture procedure is relatively complicated. The blue-light micro light emitting diode cooperates with the red light conversion layer and the green light conversion layer to emit red light and green light, so that the light quantum yield only needs to reach 70%. This embodiment is better than the solution including blue-light micro light emitting diode, green-light micro light emitting diode and red-light micro light emitting diode, and the efficiency of the display device is higher, The red light conversion layer and the green light conversion layer will leak a certain amount of blue light, and the filter layer 340 can intercept the blue light.

In an embodiment, referring to FIG. 5 and FIG. 6, the light emitting surface of the light emitting element 21 faces the thin film transistor layer 30. A light blocking layer 60 is provided on the thin film transistor layer 30, and light is transmitted at an area of the light blocking layer 60 corresponding to the light emitting element 21, and the other areas are opaque. Specifically, it is preferable that the light transmittance of the area of the light blocking layer 60 corresponding to the light emitting element 21 is higher than 60%. Of course, the present disclosure does not limit the transmittance of this area. When the light emitting element 21 emits light through the light-transmitting area 320 of the thin film transistor layer 30, the light blocking layer 60 may be provided between the package layer 70 and the protective layer 40, When the light emitting element 21 emits light from the side of the substrate layer 10, the light blocking layer 60 may be provided between the light emitting element 21 and the substrate layer 10. The light blocking layer 60 is provided with a light conversion layer 330 and a filter layer 340. The light conversion layer 330 penetrates the light blocking layer 60 and is opposite to the light-transmitting area 320 so that light can enter the light conversion layer 330. The filter layer 340 is disposed on the side of the light conversion layer 330 facing away from the light-transmitting area 320. The areas of the light blocking layer 60 excluding the light conversion layer 330 are opaque. It can be understood that the light blocking layer can prevent the light emitted by the light emitting element from being scattered.

The embodiment of the present disclosure also provides a display screen, which may be a screen of an electronic device such as a television, a smart phone, a personal digital assistant, a tablet computer, and the like. The display screen includes the display device provided by the embodiment of the present disclosure. By adding the display device provided by the present disclosure to the display screen, the manufacture procedure of the display screen is relatively simple, and the flatness is higher.

Referring to FIG. 9 and FIG. 20, an embodiment of the present disclosure also provides a method for manufacturing a display device. The manufacturing method includes:

S101: manufacturing a light emitting element 21 on a substrate layer 10;

S102: forming a first planarization layer 20 on the substrate layer 10 so that the first planarization layer 20 covers the light emitting element 21; and

S103: forming a thin film transistor layer 30 on a side of the first planarization layer 20 facing away from the substrate layer 10, so that the thin film transistor layer 30 is electrically connected to the light emitting element 21.

Specifically, the number of light emitting elements 21 is multiple, and the light emitting elements 21 may be ordinary LEDs, or may be LEDs of types such as Mini LEDs or Micro LEDs. The material of the substrate layer 10 can be glass or flexible polymer such as polyimide. The thin film transistor layer 30 has a plurality of thin film transistors, and the number of thin film transistors is preferably the same as the number of light emitting elements 21 and they are in one-to-one correspondence. It is understandable that the light emitting element 21 is first manufactured and the first planarization layer 20 is formed, and then the thin film transistor layer 30 is formed. The metal layer 312 in the thin film transistor layer 30 by array process can be used to electrically connect the light emitting element 21 without using pad bumps and eutectic metal, so as to avoid depositing too thick metal to affect the flatness. By manufacturing the light emitting element 21 on the substrate layer 10 and forming the first planarization layer 20 on the substrate layer 10, the first planarization layer 20 covers the light emitting element 21, the light emitting element 21 manufactured by this method has a higher degree of flatness.

In an embodiment, referring to FIG. 9 and FIG. 20, S101: manufacturing a light emitting element 21 on a substrate layer 10 includes:

inverting the light emitting element 21 to the substrate layer 10, so as to to make an electrical connector 211 of the light emitting element 21 face the thin film transistor layer 30.

Specifically, the electrical connector 211 is preferably a pad of the light emitting element 21. By inverting the light emitting element 21 to the substrate layer 10, the electrical connector 211 of the light emitting element 21 faces the thin film transistor layer 30, so that the electrical connector 211 is facilitated to be electrically connected to the thin film transistor layer 30.

In an embodiment, referring to FIG. 9 and FIG. 20, S103: forming a thin film transistor layer 30 on a side of the first planarization layer 20 facing away from the substrate layer 10, so that the thin film transistor layer 30 is electrically connected to the light emitting element 21, includes:

etching at a position of the first planarization layer 20 corresponding to the light emitting element 21, so that the electrical connector 211 of the light emitting element 21 is exposed from the first planarization layer 20.

Specifically, the surface of the electrical connector 211 facing the thin film transistor layer 30 is exposed from the first planarization layer 20. The etching can be chemical etching, electrolytic etching, laser etching, ultrasonic etching, and the like. The electrical connector 211 is exposed from the first planarization layer 20 by etching, so that the electrical connector 211 is electrically connected to the thin film transistor layer 30, and the manufacture procedure is relatively simple, which is beneficial to improve the yield of the display device.

In an embodiment, referring to FIG. 1 and FIG. 20, S103: forming a thin film transistor layer 30 on a side of the first planarization layer 20 facing away from the substrate layer 10, so that the thin film transistor layer 30 is electrically connected to the light emitting element 21, includes:

depositing an electrode sheet 212 on the electrical connector 211, and electrically connecting the electrode sheet 212 to the thin film transistor layer 30.

By depositing electrode sheet 212 on the electrical connector 211, there is no need to provide solder bumps and eutectic metal, and no thermal manufacture procedure is required, which is beneficial to simplify the manufacture procedure of the display device.

In an embodiment, referring to FIG. 1 and FIG. 20, S103: forming a thin film transistor layer 30 on a side of the first planarization layer 20 facing away from the substrate layer 10, so that the thin film transistor layer 30 is electrically connected to the light emitting element 21, includes:

forming a second planarization layer 301 and a metal layer 312 sequentially on the side of the first planarization layer 20 facing away from the substrate layer 10, so that the second planarization layer 301 covers the electrode sheet 212, and the metal layer 312 passes through the second planarization layer 301 and is electrically connected to the electrode sheet 212.

The second planarization layer 301 and the metal layer 312 are provided, the metal layer 312 passes through the second planarization layer 301 to be electrically connected to the electrode sheet 212, the process is relatively simple, and the second planarization layer 301 covers the electrode sheet 212, which can avoid the short-circuiting of adjacent electrode sheets 212, thereby improving the yield of the display device. Moreover, the second planarization layer 301 is provided to cover the electrode sheet 212, which can further improve the flatness of the display device.

### First Embodiment

Please refer to FIG. 1 and FIG. 9, the display device includes a substrate layer 10, a first planarization layer 20, a thin film transistor layer 30, and a protective layer 40 stacked in sequence. The material of the substrate layer 10 is colorless glass or a flexible polymer such as colorless polyimide.

A plurality of light emitting elements 21 are connected to the substrate layer 10, the first planarization layer 20 covers the plurality of light emitting elements 21 and the electrical connectors 211 of the light emitting elements 21 are exposed from the first planarization layer 20. The surface of the electrical connector 211 facing away from the substrate layer 10 is connected to the electrode sheet 212. The light emitting element 21 emits light from the side of the substrate layer 10. The light emitting element 21 is a vertical or horizontal micro light emitting diode, and specifically includes three types, i.e., red-light micro light emitting diodes, blue-light micro light emitting diodes, and green-light micro light emitting diodes.

The thin film transistor layer 30 includes a second planarization layer 301, a barrier layer 302, a light-shielding plate insulating layer 303, a gate insulating layer 304, an interlayer dielectric layer 305, and a passivation layer 306 that are sequentially stacked. In addition, the thin film transistor layer 30 further includes a light-shielding layer 307, an active layer 308, a gate layer 309, and a source-drain layer 310. The light-shielding layer 307 is provided between the light-shielding plate insulating layer 303 and the barrier layer 302, and the active layer 308 is provided on the side of the light-shielding plate insulating layer 303 facing away from the light-shielding layer 307, so that the light-shielding plate insulating layer 303 separates the light-shielding layer 307 and the active layer 308, so as to achieve the purpose of insulation. A part of the gate layer 309 is disposed between the interlayer dielectric layer 305 and the gate insulating layer 304, and the other part passes through the gate insulating layer 304 and the light-shielding plate insulating layer 303 and is connected to the light-shielding layer 307. The active layer 308 is provided between the gate insulating layer 304 and the light-shielding plate insulating layer 303. The source-drain layer 310 is divided into a source and a drain, and both the source and the drain can drive the light emitting element 21. A part of the source in the source-drain layer 310 is disposed between the passivation layer 306 and the interlayer dielectric layer 305, and the other part passes through the interlayer dielectric layer 305 and the gate insulating layer 304 to be connected to the active layer 308. A part of the drain in the source-drain layer 310 is provided between the passivation layer 306 and the interlayer dielectric layer 305, and the other part sequentially passes through the interlayer dielectric layer 305, the gate insulating layer 304 and the light-shielding plate insulating layer to be connected to the metal layer 312, so as to supply power to the light emitting element 21. The positions of the source (source electrode) and the drain (drain electrode) in this embodiment are interchangeable.

### Second Embodiment

Please refer to FIG. 2 and FIG. 10, the display device includes a substrate layer 10, a first planarization layer 20, a thin film transistor layer 30, and a protective layer 40 in sequence. The material of the substrate layer 10 is glass or a flexible polymer such as polyimide, which can transmit light or cannot transmit light.

A plurality of light emitting elements 21 are connected to the substrate layer 10, the first planarization layer 20 covers the plurality of light emitting elements 21, and the electrical connectors 211 of the light emitting elements 21 are exposed from the first planarization layer 20. The surface of the electrical connector 211 facing away from the substrate layer 10 is connected the electrode sheet 212. The light emitting element 21 is a vertical or horizontal micro light emitting diode, and specifically includes three types, i.e., red-light micro light emitting diodes, blue-light micro light emitting diodes, and green-light micro light emitting diodes.

The thin film transistor layer 30 has a light-transmitting area 320, and the light-transmitting area 320 is opposite to the light emitting element 21, and the light emitting element 21 can emit light through the light-transmitting area 320. The structure of each layer in the thin film transistor layer 30, such as the second planarization layer 301, the barrier layer 302, and the light-shielding plate insulating layer 303, can refer to the first embodiment.

### Third Embodiment

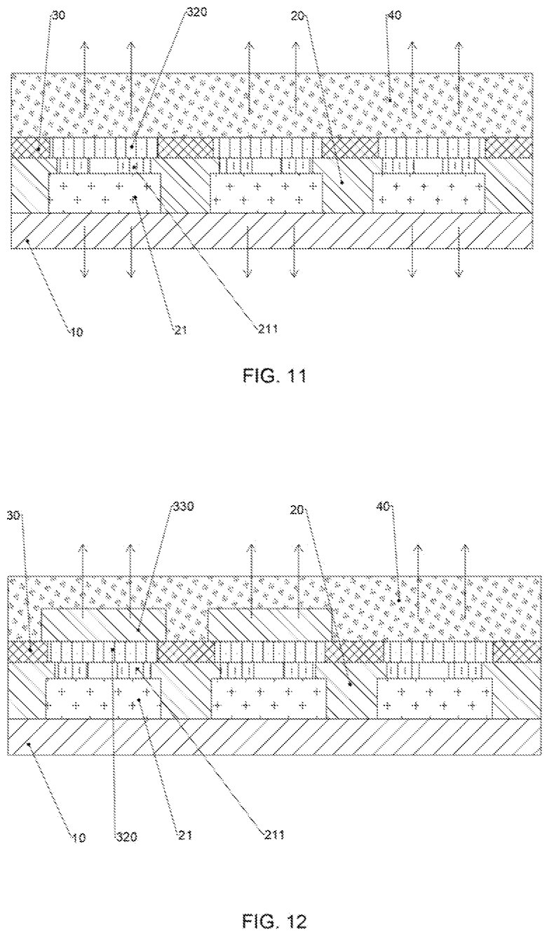

Please refer to FIG. 2 and FIG. 11, the display device includes a substrate layer 10, a first planarization layer 20, a thin film transistor layer 30, and a protective layer 40 in sequence. The material of the substrate layer 10 is colorless glass or a flexible polymer such as colorless polyimide.

A plurality of light emitting elements 21 are connected to the substrate layer 10, the first planarization layer 20 covers the plurality of light emitting elements 21 and the electrical connectors 211 of the light emitting elements 21 are exposed from the first planarization layer 20. The surface of the electrical connector 211 facing away from the substrate layer 10 is connected to the electrode sheet 212. The light emitting element 21 is a vertical or horizontal micro light emitting diode, and specifically includes three types, i.e., red-light micro light emitting diodes, blue-light micro light emitting diodes, and green-light micro light emitting diodes.

The thin film transistor layer 30 has a light-transmitting area 320, and the light-transmitting area 320 is opposite to the light emitting element 21, and the light emitting element 21 can emit light through the light-transmitting area 320. The structure of each layer in the thin film transistor layer 30, such as the second planarization layer 301, the barrier layer 302, and the light-shielding plate insulating layer 303, can refer to the first embodiment.

The light emitting element 21 in this embodiment emits light at the side of the thin film transistor layer 30 and the side of the substrate layer 10 at the same time.

### Fourth Embodiment

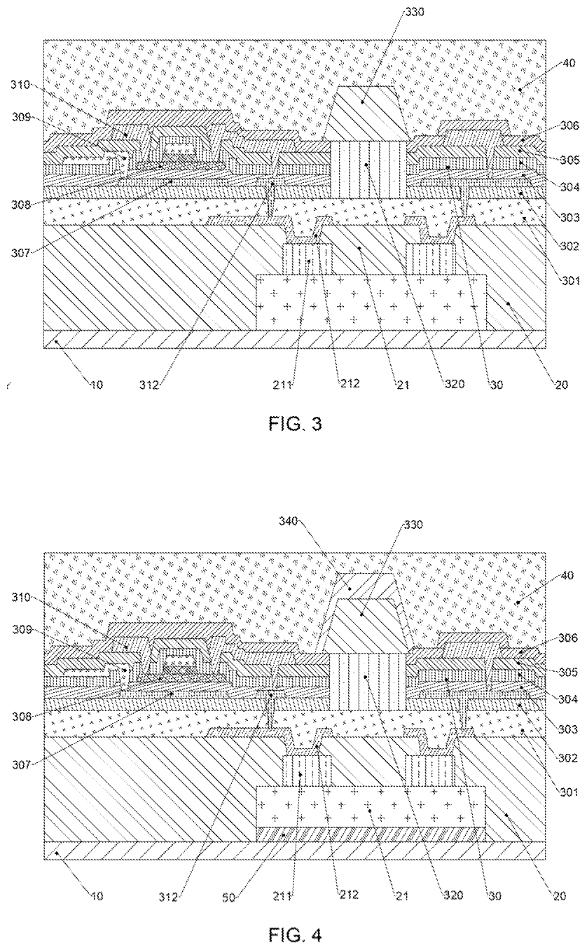

Please refer to FIG. 3 and FIG. 12 the display device includes a substrate layer 10, a first planarization layer 20, a thin film transistor layer 30, and a protective layer 40 in sequence. The material of the substrate layer 10 is colorless glass or a flexible polymer such as colorless polyimide.

A plurality of light emitting elements 21 are connected to the substrate layer 10, the first planarization layer 20 covers the plurality of light emitting elements 21, and the electrical connectors 211 of the light emitting elements 21 are exposed from the first planarization layer 20. The surface of the electrical connector 211 facing away from the substrate layer 10 is connected to the electrode sheet 212.

The thin film transistor layer 30 has a light-transmitting area 320, and the light-transmitting area 320 is opposite to the light emitting element 21, and the light emitting element 21 can emit light through the light-transmitting area 320. A light conversion layer 330 is connected to the side of the light-transmitting area 320 facing away from the light emitting element 21, and the light conversion layer 330 includes a green light conversion layer and a red light conversion layer. The light emitting elements 21 of this embodiment are all vertical or horizontal blue-light micro light emitting diodes. The blue-light micro light emitting diodes cooperate with the green light conversion layer and the red light conversion layer, so as to a light in three colors of red, blue and green.

The structure of each layer in the thin film transistor layer 30, such as the second planarization layer 301, the barrier layer 302, and the light-shielding plate insulating layer 303, can refer to the first embodiment.

The light emitting element 21 in this embodiment emits light on the side at the thin film transistor layer 30 through the light-transmitting area 320.

### Fifth Embodiment

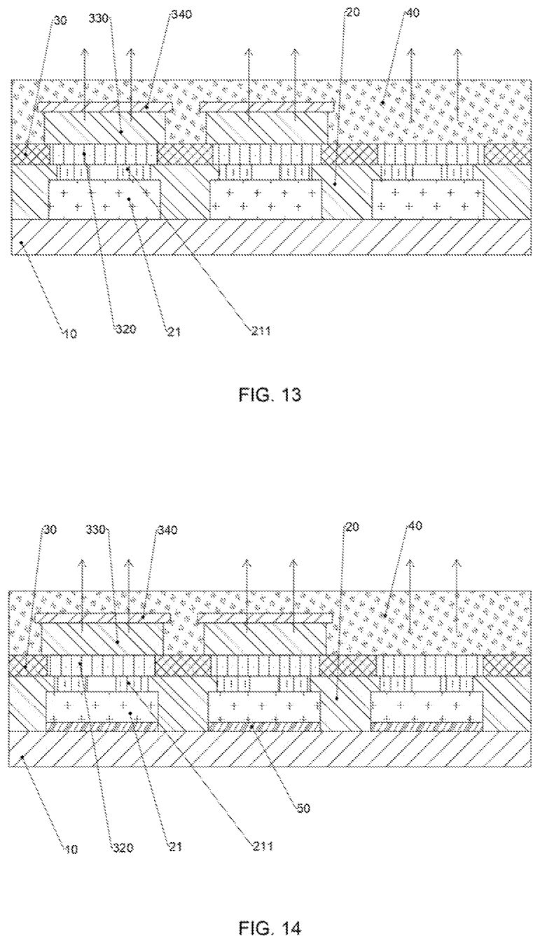

Please refer to FIG. 4 and FIG. 13 the display device includes a substrate layer 10, a first planarization layer 20, a thin film transistor layer 30, and a protective layer 40 in sequence. The material of the substrate layer 10 is colorless glass or a flexible polymer such as colorless polyimide.

A plurality of light emitting elements 21 are connected to the substrate layer 10, the first planarization layer 20 covers the plurality of light emitting elements 21 and the electrical connectors 211 of the light emitting elements 21 are exposed from the first planarization layer 20. The surface of the electrical connector 211 facing away from the substrate layer 10 is connected to the electrode sheet 212.

The thin film transistor layer 30 has a light-transmitting area 320, and the light-transmitting area 320 is opposite to the light emitting element 21, and the light emitting element 21 can emit light through the light-transmitting area 320. A light conversion layer 330 is connected to the side of the light-transmitting area 320 facing away from the light emitting element 21, and the light conversion layer 330 includes a green light conversion layer and a red light conversion layer. The light emitting elements 21 of this embodiment are all vertical or horizontal blue-light micro light emitting diodes. The blue-light micro light emitting diodes cooperate with the green light conversion layer and the red light conversion layer, so as to emit light in three colors of red, blue and green. The light conversion layer 330 is provided with a filter layer 340, and the filter layer 340 can intercept the blue light leaked from the light conversion layer 330.

The structure of each layer in the thin film transistor layer 30, such as the second planarization layer 301, the barrier layer 302, and the light-shielding plate insulating layer 303, can refer to the first embodiment.

The light emitting element 21 in this embodiment emits light on the side at the thin film transistor layer 30 through the light-transmitting area 320.

### Sixth Embodiment

Please refer to FIG. 4 and FIG. 14, the display device includes a substrate layer 10, a first planarization layer 20, a thin film transistor layer 30, and a protective layer 40 in sequence. The material of the substrate layer 10 is colorless glass or a flexible polymer such as colorless polyimide.

A reflective layer 50 is connected to the substrate layer 10, and a plurality of light emitting elements 21 are connected to the surface of the reflective layer 50 facing away from the substrate layer 10. The reflective layer 50 can reflect light emitted from the light emitting element 21 in various directions to the thin film transistor layer 30 to emit light. The first planarization layer 20 covers the plurality of light emitting elements 21, and the electrical connectors 211 of the light emitting elements 21 are exposed from the first planarization layer 20. The surface of the electrical connector 211 facing away from the substrate layer 10 is connected to the electrode sheet 212.

The thin film transistor layer 30 has a light-transmitting area 320, and the light-transmitting area 320 is opposite to the light emitting element 21, and the light emitting element 21 can emit light through the light-transmitting area 320. A light conversion layer 330 is connected to the side of the light-transmitting area 320 facing away from the light emitting element 21, and the light conversion layer 330 includes a green light conversion layer and a red light conversion layer. The light emitting elements 21 of this embodiment are all vertical or horizontal blue-light micro light emitting diodes. The blue-light micro light emitting diodes cooperate with the green light conversion layer and the red light conversion layer, so as to emit light in three colors of red, blue and green. The light conversion layer 330 is provided with a filter layer 340, and the filter layer 340 can intercept the blue light leaked from the light conversion layer 330.

The structure of each layer in the thin film transistor layer 30, such as the second planarization layer 301, the barrier layer 302, and the light-shielding plate insulating layer 303, can refer to the first embodiment.

The light emitting element 21 in this embodiment emits light on the side at the thin film transistor layer 30 through the light-transmitting area 320.

### Seventh Embodiment

Please refer to FIG. 5 and FIG. 14, the display device includes a substrate layer 10, a first planarization layer 20, a thin film transistor layer 30, a protective layer 40, a light blocking layer 60, and a package layer 70 in sequence. The material of the substrate layer 10 is colorless glass or a flexible polymer such as colorless polyimide.

A reflective layer 50 is connected to the substrate layer 10, and a plurality of light emitting elements 21 are connected to the surface of the reflective layer 50 facing away from the substrate layer 10. The reflective layer 50 can reflect light emitted from the light emitting element 21 in various directions to the thin film transistor layer 30 to emit light. The first planarization layer 20 covers the plurality of light emitting elements 21, and the electrical connectors 211 of the light emitting elements 21 are exposed from the first planarization layer 20. The surface of the electrical connector 211 facing away from the substrate layer 10 is connected to the electrode sheet 212.

The thin film transistor layer 30 has a light-transmitting area 320, and the light-transmitting area 320 is opposite to the light emitting element 21, and the light emitting element 21 can emit light through the light-transmitting area 320. The light blocking layer 60 is provided with a hole opposite to the light-transmitting area 320, and the light conversion layer 330 is installed in the hole. The light conversion layer 330 includes a green light conversion layer and a red light conversion layer. The light emitting elements 21 of this embodiment are all vertical or horizontal blue-light micro light emitting diodes, The blue-light micro light emitting diodes cooperate with the green light conversion layer and the red light conversion layer, so as to emit light in three colors of red, blue and green. A filter layer 340 is provided on the surface of the light conversion layer 330 facing away from the protective layer 40, and the filter layer 340 can intercept the blue light leaked from the light conversion layer 330. Light can only be emitted through the light conversion layer 330 of the light blocking layer 60, and other positions of the light blocking layer 60 are opaque.

The structure of each layer in the thin film transistor layer 30, such as the second planarization layer 301, the barrier layer 302, and the light-shielding plate insulating layer 303, can refer to the first embodiment,

The light emitting element 21 in this embodiment emits light on the side at the thin film transistor layer 30 through the light-transmitting area 320.

### Eighth Embodiment

Please refer to FIG. 6 and FIG. 8, the display device includes a substrate layer 10, a first planarization layer 20, the thin film transistor layer 30, the protective layer 40, the light blocking layer 60, and the package layer 70 in sequence. The material of the substrate layer 10 is colorless glass or a flexible polymer such as colorless polyimide.

The structures of the package layer 70, the light blocking layer 60, the protective layer 40, the thin film transistor layer 30, the planarization layer, and the substrate layer 10 can all refer to the embodiment 7. The difference is that the light emitting element 21 in this embodiment is a vertical light emitting diode, preferably a vertical micro light emitting diode. The upper electrode of the vertical light emitting diode is an electrode sheet 212, and the lower electrode 51 is a reflective layer 50 made of a metal material. The reflective layer 50 can reflect the light of the light emitting element 21 and drive the light emitting element 21.

The light emitting element 21 in this embodiment emits light on the side at the thin film transistor layer 30 through the light-transmitting area 320.

### Ninth Embodiment

Please refer to FIG. 7 and FIG. 15, the display device includes a substrate layer 10, a first planarization layer 20, a thin film transistor layer 30, and a protective layer 40. The substrate layer 10, the first planarization layer 20 and the thin film transistor layer 30 are stacked, and the protective layer 40 surrounds the substrate layer 10, the first planarization layer 20 and the thin film transistor layer 30. The protective layer 40 is made of an elastic material, so that the display device is stretchable. The material of the substrate layer 10 is glass or a flexible polymer such as polyimide, which can transmit light or cannot transmit light. Adjacent light emitting elements 21 are connected by a flexible connector 13, and the flexible connector 13 is a patterned thin film transistor layer 30, and/or a patterned substrate layer 10 made of polyimide. It can be understood that the display device in this embodiment includes a plurality of display units, and each display unit includes a light emitting element 21, a thin film transistor, and a substrate layer 10 at a corresponding position. Since the thin film transistor and the substrate layer 10 at the corresponding position are both connected to the light emitting element 21, the flexible connector 13 connects the thin film transistors of the adjacent display units, thereby connecting the adjacent light emitting elements 21; or the flexible connector 13 connects the substrate layers 10 of the adjacent display units, thereby connecting the adjacent light emitting elements 21.

A plurality of light emitting elements 21 are connected to the substrate layer 10, the first planarization layer 20 covers the plurality of light emitting elements 21, and the electrical connectors 211 of the light emitting elements 21 are exposed from the first planarization layer 20. The surface of the electrical connector 211 facing away from the substrate layer 10 is connected to the electrode sheet 212. The light emitting element 21 is a vertical or horizontal micro light emitting diode, and specifically includes three types, i.e., red-light micro light emitting diodes, blue-light micro light emitting diodes, and green-light micro light emitting diodes.

The thin film transistor layer 30 has a light-transmitting area 320, and the light-transmitting area 320 is opposite to the light emitting element 21, and the light emitting element 21 can emit light through the light-transmitting area 320. The structure of each layer in the thin film transistor layer 30, such as the second planarization layer 301, the barrier layer 302, and the light-shielding plate insulating layer 303, can refer to the first embodiment.

The light emitting element 21 in this embodiment emits light on the side at the thin film transistor layer 30 through the light-transmitting area 320.

### Tenth Embodiment

Please refer to FIG. 8 and FIG. 16, the display device includes a substrate layer 10, a first planarization layer 20, a thin film transistor layer 30, and a protective layer 40, The structures of the substrate layer 10, the first planarization layer 20, the thin film transistor layer 30, and the protective layer 40 can all refer to the embodiment 9. It should be noted that the substrate layer 10 in this embodiment is made of a flexible polymer, such as colorless polyimide, that can transmit light. The thin film transistor layer 30 does not have a light-transmitting area 320, and the light emitting element 21 emits light from the side at the substrate layer 10.

The light emitting element 21 is a vertical micro light emitting diode, The two opposite sides of the light emitting element 21 are respectively provided with an upper electrode and a lower electrode 51. The upper electrode is an electrode sheet 212. The lower electrode 51 is connected to the surface of the substrate layer 10 facing the light emitting element 21. Since the light emitted by the light emitting element 21 needs to pass through the lower electrode 51 to be emitted from the substrate layer 10 the lower electrode 51 is made of transparent conductive materials such as indium tin oxide and nano silver.

### Eleventh Embodiment

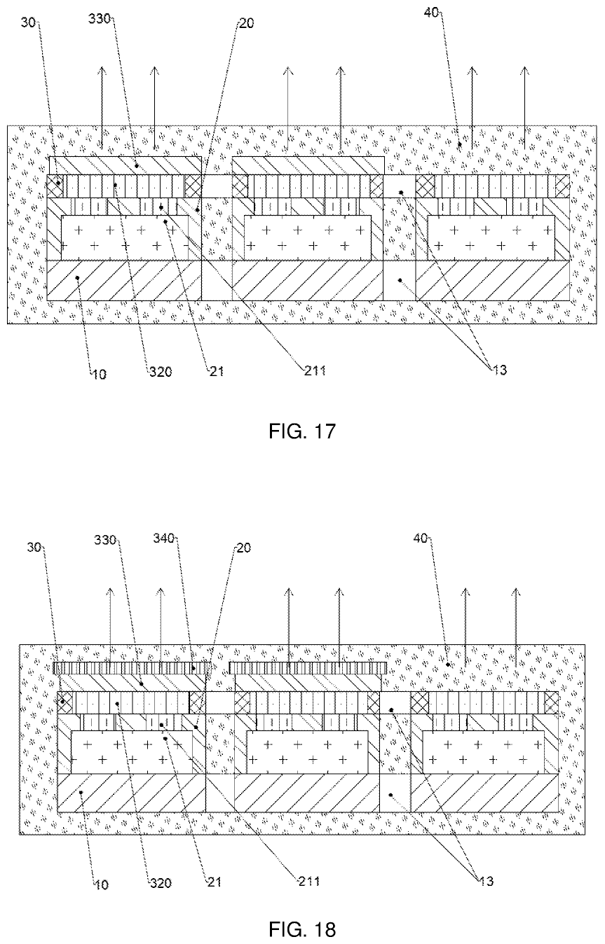

Please refer to FIG. 17, the display device includes a substrate layer 10, a first planarization layer 20, a thin film transistor layer 30, and a protective layer 40. The structures of the substrate layer 10, the first planarization layer 20, the thin film transistor layer 30 and the protective layer 40 can refer to the embodiment 9. The light emitting element 21 in this embodiment is a blue-light micro light emitting diode, and the light-transmitting area 320 of the thin film transistor is provided with a light conversion layer 330 on the side facing away from the first planarization layer 20, and the function of the light conversion layer 330 will not be described again.

Specifically, referring to FIG. 3, the light conversion layer 330 may be provided on the surface of the light-transmitting area 320. Alternatively, referring to FIG. 5, the light conversion layer 330 may be provided at the light blocking layer 60.

The light emitting element 21 in this embodiment emits light on the side at the thin film transistor.

### Twelfth Embodiment

Please refer to FIG. 18, the display device includes a substrate layer 10, a first planarization layer 20, a thin film transistor layer 30, and a protective layer 40. The structures of the substrate layer 10, the first planarization layer 20, the thin film transistor layer 30 and the protective layer 40 can refer to the embodiment 9. In this embodiment, on the basis of the embodiment 11, a filter layer 340 is added. The function of the filter layer 340 will not be described again.

Specifically, referring to FIG. 4, the filter layer 340 encloses the outer surface of the light conversion layer 330 to prevent the light conversion layer 330 from leaking blue light. Alternatively, referring to FIG. 5, the filter layer 340 and the light conversion layer 330 are both provided at the light blocking layer 60.

What is disclosed above is only a preferred embodiment of the present disclosure. Of course, it cannot be used to limit the scope of the claims of the present disclosure. A person of ordinary skill in the art can understand that all or part of the processes for implementing the foregoing embodiments and equivalent changes made in accordance with the claims of the present disclosure still fall within the scope of the present disclosure

What is claimed is:

1. A display device, comprising:
a substrate layer, a first planarization layer and a thin film transistor layer that are stacked; and
a plurality of light emitting elements located on the planarization layer,
wherein an electrical connector is located at a side of the light emitting element facing the thin film transistor layer, and the electrical connector is exposed from the first planarization layer and is electrically connected to the thin film transistor layer.

2. The display device according to claim 1, wherein each of the light emitting elements is a micro light emitting diode.

3. The display device according to claim 1, wherein the electrical connector is a pad of the light emitting element.

4. The display device according to claim 1, further comprising a package layer covering the thin film transistor layer, and the thin film transistor layer is located between the package layer and the first planarization layer.

5. The display device according to claim 1, wherein the thin film transistor layer comprises a metal layer, and the metal layer passes through the thin film transistor layer and is electrically connected to the electrical connector.

6. The display device according to claim 5, wherein the thin film transistor layer further comprises a second planarization layer, the light emitting element comprises an electrode sheet connected to the electrical connector, wherein the second planarization layer covers the electrode sheet, and the metal layer passes through the second planarization layer and is electrically connected to the electrode sheet.

7. The display device according to claim 6, wherein the plurality of light emitting elements are arranged at intervals; the thin film transistor layer comprises a plurality of thin film transistors in one-to-one correspondence with the light emitting elements; and two adjacent light emitting elements are connected by a flexible connector.

8. The display device according to claim 7, wherein the flexible connector comprises at least one of a patterned substrate layer, a patterned thin film transistor layer and a patterned first planarization layer, wherein the patterned substrate layer is of a flexible polymer film.

9. The display device according to claim 8, wherein the patterned thin film transistor layer is partially etched.

10. The display device according to claim 9, wherein the patterned thin film transistor layer comprises a second planarization layer, a barrier layer, a light-shielding plate insulating layer, a gate insulating layer, an interlayer dielectric layer and a passivation layer that are stacked.

11. The display device according to claim 10, wherein at least one of the interlayer dielectric layer, the gate insulating layer, the light-shielding plate insulating layer and the barrier layer in the patterned thin film transistor layer is etched.

12. The display device according to claim 10, wherein the thin film transistor layer further comprises a light-shielding layer, an active layer, a gate layer and a source-drain layer, wherein the light-shielding plate insulating layer insulates the active layer from the light-shielding layer; the gate insulating layer insulates the gate layer from the active layer; the interlayer dielectric layer insulates the source-drain layer from the gate layer; and the passivation layer overall protects the thin film transistor layer.

13. The display device according to claim 7, wherein the flexible connector is curved.

14. The display device according to claim 6, wherein a light emitting surface of each of the light emitting elements faces at least one of the thin film transistor layer and the substrate layer.

15. The display device according to claim 14, wherein at least one of the thin film transistor layer and the substrate layer on a side of each of the light emitting elements facing the light emitting surface has a corresponding light-transmitting area.

16. The display device according to claim 15, wherein the light-transmitting area of the thin film transistor layer corresponding to each of the light emitting elements is made of a light-transmitting material, or the substrate layer is made of a light-transmitting material.

17. The display device according to claim 6, wherein a reflective layer is located on a shady face of each of the light emitting element away from the light emitting surface

18. The display device according to claim 17, wherein the reflective layer is electrically connected to each of the light emitting elements, and the reflective layer and the electrode sheet jointly drive each of the light emitting elements

19. The display device according to claim 14, wherein the light emitting surface of each of the light emitting element faces the thin film transistor layer, and a light blocking layer is located on the thin film transistor layer, wherein light is transmitted at an area of the light blocking layer corresponding to each of the light emitting elements, and the other areas of the light blocking layer are opaque.

20. A display screen, comprising the display device, wherein the display device comprises:
a substrate layer, a first planarization layer and a thin film transistor layer that are stacked; and
a plurality of light emitting elements located on the planarization layer,
wherein an electrical connector is located at a side of the light emitting element facing the thin film transistor layer, and the electrical connector is exposed from the first planarization layer and is electrically connected to the thin film transistor layer.
